(19) United States
(12) Patent Application Publication
(10) Pub. No.: US 2025/0351649 A1
(43) Pub. Date: Nov. 13, 2025

(54) DISPLAY DEVICE

(71) Applicant: Samsung Display Co., LTD., Yongin-si (KR)

(72) Inventors: Hyung Guen YOON, Yongin-si (KR); Suk Hoon KANG, Yongin-si (KR); Seung Beom PARK, Yongin-si (KR)

(21) Appl. No.: 19/063,844

(22) Filed: Feb. 26, 2025

(30) Foreign Application Priority Data
May 8, 2024 (KR) 10-2024-0060674

(51) Int. Cl. H10H 29/851; H10H 29/80; H10H 29/85; H10H 29/855

(52) U.S. Cl. CPC H10H 29/8512; H10H 29/8514; H10H 29/8517; H10H 29/855; H10H 29/882

(57) ABSTRACT

A display device according to an embodiment includes a display panel, and a color conversion layer disposed on the display panel, wherein the color conversion layer includes a quantum dot and a scatterer, the scatterer includes a first particle having a first diameter, and the first diameter is from about 100 nm to about 180 nm.

### CROSS-REFERENCE TO RELATED APPLICATION

The present application claims priority to and the benefit of Korean Patent Application No. 10-2024-0060674, filed on May 8, 2024, in the Korean Intellectual Property Office, the entire disclosure of which is incorporated herein by reference.

### BACKGROUND

### 1. Field

This disclosure relates to a display device.

### 2. Description of the Related Art

As the demand for display devices grows, the need or desire for versatile display devices suitable for various purposes is also increasing. Accordingly, display devices are gradually become larger and/or thinner, with a rising demand (or desire) for display devices that offer high light output efficiency and color purity.

Additionally, display device are being used in a wide range of applications, such as large outdoor screens, in concert halls, walls, ceilings, road facilities, and/or the like. In these cases, reflection of external light on the surface of the display device may cause an unclear (or blurry) screen.

Moreover, display devices are not only in small and medium-sized electronic products like home TVs and/or computer monitors, but also in portable electronic products such as smartphones, tablet PCs, and/or laptops. These applications may also be affected by external light sources.

When viewing (observing) various types (kinds) of display devices in the presence of external light, there is a need or desire for the display devices (displays) that can maintain the color and brightness (of the screen), ensuring a clear screen regardless of external light conditions.

### SUMMARY

Aspects according to one or more embodiments of the present disclosure are directed toward a display device including a scatterer introduced into the color conversion layer to increase the light output efficiency of the display device, and the size and concentration of the scatterer are adjusted to reduce scattered reflection caused by external light occurring on the surface of the scatterer. This is, the embodiments introduce a scatterer into the color conversion layer to enhance the light output efficiency of the display device. Additionally, the size and concentration of the scatterer are adjusted to reduce or minimize scattered reflection caused by external light on the surface of the scatterer.

Additional aspects of embodiments will be set forth in part in the description, which follows and, in part, will be apparent from the description, or may be learned by practice of the presented embodiments of the disclosure.

A display device according to one or more embodiments includes a display panel, and a color conversion layer arranged on the display panel, wherein the color conversion layer includes a quantum dot and a scatterer, the scatterer includes a first particle having a first diameter, and the first diameter is from about 100 nm to about 180 nm.

The scatterer included in the display device may be TiO₂.

The scatterer included in the display device may have a spherical shape.

A grain form of the scatterer (the TiO₂) may include at least one of rutile or anatase.

When the grain form of the scatterer (the TiO₂) is at least one of rutile or anatase, an average grain size may be about 20 nm to about 30 nm.

The display panel may include a first substrate and a light emitting element arranged on the first substrate, the color conversion layer is arranged on the light emitting element, and the scatterer may be dispersed in particulate form within the color conversion layer.

A concentration (e.g., amount) of the scatterer may be more than 4 wt % based on a total weight (100 wt %) of the quantum dot. For example, the scatterer is 4 wt % or greater in amount based on a total weight of the quantum dot.

The display device may further include a color filter arranged on the color conversion layer and a micro-lens array overlapping with the color filter.

The micro-lens array may have a refractive index of 1.5 or more.

The display device may further include an overcoat layer overlapping the micro-lens array, and a refractive index of the overcoat layer may be greater than a refractive index of the lenses constituting the micro-lens array by 0.05 or more (i.e., a refractive index of the overcoat layer may be 0.05 or more greater than a refractive index of lenses constituting the micro-lens array).

A display device according to one or more embodiments includes a display panel and a color conversion layer arranged on the display panel, wherein the color conversion layer includes a quantum dot and a scatterer, and the scatterer includes at least two particles having different diameters, where the particles may have a diameter of about 140 nm to about 160 nm.

The scatterer included in the display device may be TiO₂.

The scatterer included in the display device may have a spherical shape.

A grain form of the scatterer (the TiO₂) may include at least one of rutile or anatase.

The display panel further includes a first substrate and a light emitting element arranged on the first substrate, wherein the color conversion layer may be arranged on the light emitting element, and the scatterer may be dispersed in particulate form within the color conversion layer.

A particle size value D₁₀ corresponding to a cumulative distribution percentage of particles in a particle size distribution of TiO₂ of 10% is greater than or equal to an average particle size D_{avg} of TiO₂ minus 50 nm, and a particle size value D₉₀ corresponding to a cumulative distribution percentage of particles in a particle size distribution of TiO₂ of 90% may be less than or equal to the average particle size D_{avg} of TiO₂ plus 50 nm.

A particle size value D₉₀ corresponding to a cumulative distribution percentage of particles in a particle size distribution of TiO₂ of 90% may be less than or equal to an average particle size D_{avg} of TiO₂ plus 100 nm.

The display device may further include a color filter arranged on the color conversion layer and a micro-lens array overlapping with the color filter.

The micro-lens array may have a refractive index of 1.5 or more.

The display device may further include an overcoat layer overlapping with the micro-lens array, and a refractive index of the overcoat layer is greater than a refractive index of the lenses constituting the micro-lens array by 0.05 or more (i.e., a refractive index of the overcoat layer may be 0.05 or more greater than a refractive index of lenses constituting the micro-lens array).

According to one or more embodiments, by introducing the scatterer in the color conversion layer, the light output efficiency of the display device can be increased, and by adjusting the size and concentration of the scatterer, the scattered reflection caused by external light occurring on the surface of the scatterer can be reduced.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic exploded perspective view of a display device according to an embodiment.

FIG. 2 is a schematic cross-sectional view of a display panel according to an embodiment.

FIG. 3 is a cross-sectional view of a display panel according to an embodiment.

FIG. 4(a) is a schematic perspective view of the color conversion layer if (e.g., when) it has a monodispersed scatterer, and (b) is a schematic perspective view of the color conversion layer if (e.g., when) it has a polydispersed scatterer.

FIG. 5(a) is a schematic diagram of a color conversion layer without a scatterer, and FIG. 5(b) is a schematic diagram of a color conversion layer with a scatterer.

FIG. 6(a) is a diagram showing a surface on which incident light is mirror-reflected, and FIG. 6(b) is a diagram showing a surface on which incident light is scattered and reflected.

FIG. 7 is a diagram showing the structure of an anatase form of TiO₂ corresponding to a scatterer in an embodiment.

FIG. 8 is a diagram showing the structure of a rutile form of TiO₂, corresponding to a scatterer in an embodiment.

FIG. 9 is a cross-sectional view of a display panel including a micro-lens array according to an embodiment.

FIG. 10 is a cross-sectional view of a display panel including a micro-lens array according to an embodiment.

FIG. 11 is a cross-sectional view of a display panel including a micro-lens array according to an embodiment.

FIG. 12 is a graph showing the reflectance of a display panel according to an embodiment (Embodiment 1 or Experimental Example 1) and the reflectance of a display panel of an embodiment to be compared with Comparative Example 1.

### DETAILED DESCRIPTION

Hereinafter, with reference to the attached drawings, one or more suitable embodiments of the present disclosure will be described in more detail so that those skilled in the art can easily implement the present disclosure. The present disclosure may be implemented in many different forms and is not limited to the embodiments described herein.

In order to clearly explain the present disclosure, parts that are not relevant to the description are omitted, and substantially identical or similar components are assigned the same reference numerals throughout the specification.

In addition, the size and thickness of each component shown in the drawings are arbitrarily shown for convenience of explanation, so the present disclosure is not necessarily limited to that which is shown. In the drawings, the thickness may be enlarged to clearly show one or more suitable layers and regions. And in the drawings, for convenience of explanation, the thicknesses of some layers and regions may be exaggerated.

Additionally, if (e.g., when) a part of a layer, membrane, region, or plate is said to be “above” or “on” another part, this includes not only cases where it is “directly above” or “directly on” the other part, but also cases where there is another part in between. In contrast, if (e.g., when) an element is referred to as being “directly on” another element, there are no intervening elements present. In addition, being “above” or “on” a reference part refers to being arranged above or below the reference part, and does not necessarily refer to being arranged “above” or “on” the reference part in the direction opposite to gravity.

In addition, throughout the specification, if (e.g., when) a part is said to “include” a certain component, this refers to that the part may further include other components rather than excluding other components, unless specifically stated to the contrary.

In addition, throughout the specification, if (e.g., when) reference is made to “on a plane,” this refers to if (e.g., when) the target part is viewed from above, and if (e.g., when) reference is made to “in a cross-section,” this refers to if (e.g., when) a cross-section of the target portion is cut vertically and viewed from the side.

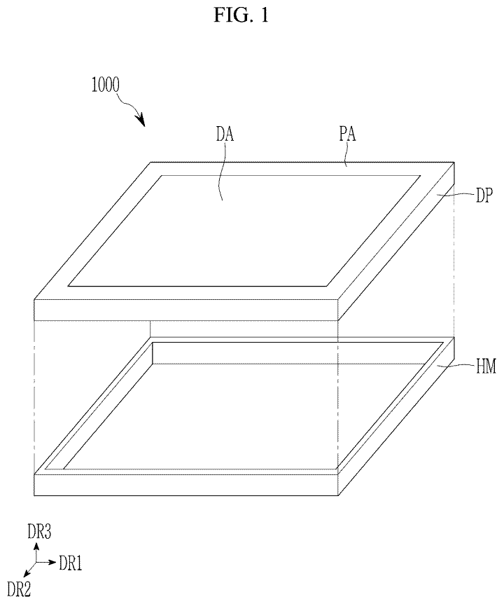

Hereinafter, a display device according to an embodiment will be described with reference to FIG. 1. FIG. 1 is a schematic exploded perspective view of a display device according to an embodiment.

Referring to FIG. 1, the display device 1000 according to an embodiment may include a display panel DP and a housing HM.

One side of the display panel DP on which the image is displayed is parallel to the side defined by the first direction DR1 and the second direction DR2. The third direction DR3 indicates the normal direction to the one side on which the image is displayed, that is, the thickness direction of the display panel DP. The front (or upper) and back (or lower) surfaces of each member are separated in the third direction DR3. However, the directions indicated by the first to third directions DR1, DR2, and DR3 are relative concepts and can be converted to other suitable directions.

The display panel DP may be a flat rigid display panel, but the present disclosure is not limited thereto and the display panel DP may be a flexible display panel. In one or more embodiments, the display panel DP may be made of an organic light emitting display panel. However, the type (kind) of display panel DP is not limited thereto and the display panel DP may be made of one or more suitable types (kinds) of panels. For example, the display panel DP may be made of a liquid crystal display panel, an electrophoretic display panel, an electrowetting display panel, and/or the like. Additionally, the display panel DP may be made of a next-generation display panel such as a micro light emitting diode display panel, a quantum dot light emitting diode display panel, and/or a quantum dot organic light emitting diode display panel.

Quantum dot light emitting diode display panels are made by attaching a film containing quantum dots or by forming (e.g., the light emitting diode display panels) with a material containing quantum dots. Quantum dots are particles made of inorganic materials such as indium and/or cadmium, emit light on their own, and have a diameter of several nanometers or less. By controlling the particle size of quantum dots, light of a desired or suitable color can be displayed. The quantum dot organic light emitting diode display panel uses a blue organic light emitting diode as a light source and displays color by attaching a film containing red and green quantum dots on the light source, or by depositing a material containing red and green quantum dots (e.g., over the light source) to achieve color. The display panel DP according to an embodiment may be made of one or more suitable other display panels.

As shown in FIG. 1, the display panel DP includes a display area DA where an image is displayed, and a non-display area PA adjacent to the display area DA. The non-display area PA is an area where images are not displayed. For example, the display area DA may have a square shape, and the non-display area PA may have a shape around (e.g., surrounding) the display area DA. However, the shape of the display area DA and the non-display area PA may be relatively designed without being limited thereto.

The housing HM provides a set or predetermined internal space. The display panel DP is mounted inside the housing HM. In addition to the display panel DP, one or more suitable electronic components, such as a power supply unit, a storage device, and/or an audio input/output module, may be mounted inside the housing HM.

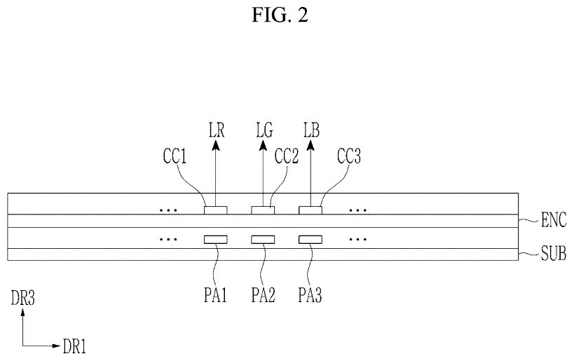

Hereinafter, the display area of the display panel according to an embodiment will be described with reference to FIG. 2. FIG. 2 is a schematic cross-sectional view of a display panel according to an embodiment.

Referring to FIG. 2, a plurality of pixels PA1, PA2, and PA3 may be formed on the substrate SUB corresponding to the display area DA of FIG. 1. Each pixel PA1, PA2, and PA3 may include a plurality of transistors and a light emitting element connected thereto.

FIG. 2 shows an embodiment in which a plurality of pixels PA1, PA2, and PA3 are repeatedly arranged in a stripe shape, but the present disclosure is not limited thereto, and the shape and arrangement of each pixel may be modified in one or more suitable ways.

An encapsulation layer ENC may be arranged on a plurality of pixels PA1, PA2, and PA3. The display area DA may be protected from external air or moisture through the encapsulation layer ENC. The encapsulation layer ENC may be integrally provided to overlap the entire surface of the display area DA, and may also be partially arranged on the non-display area PA.

A first color conversion unit CC1, a second color conversion unit CC2, and a transmission unit CC3 may be arranged on the encapsulation layer ENC. The first color conversion unit CC1 overlaps with the first pixel PA1, the second color conversion unit CC2 overlaps with the second pixel PA2, and the transmission unit CC3 can overlap with the third pixel PA3.

Light emitted from the first pixel PA1 may pass through the first color conversion unit CC1 to provide red light LR. Light emitted from the second pixel PA2 may pass through the second color conversion unit CC2 to provide green light LG. Light emitted from the third pixel PA3 may pass through the transmission part CC3 to provide incident blue light LB.

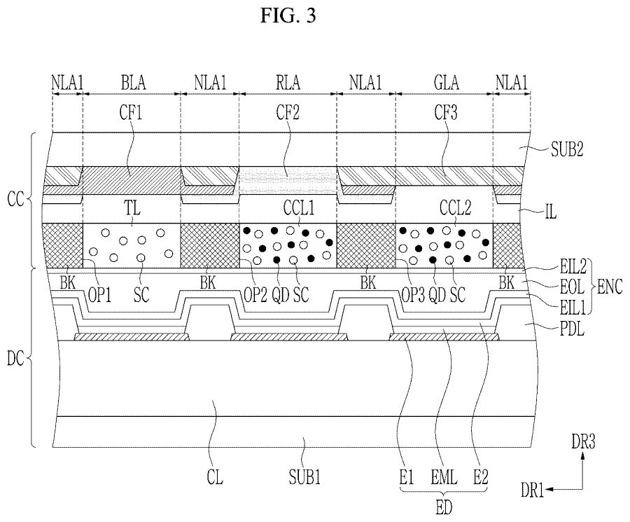

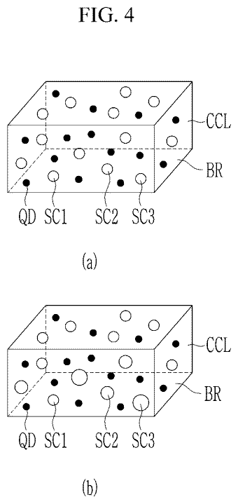

Hereinafter, the structure of the display panel according to an embodiment will be described in more detail with reference to FIGS. 3 and 4. FIG. 3 is a cross-sectional view of a display panel according to an embodiment, and FIG. 4 is a schematic perspective view of an opening arranged on a color conversion layer of the display panel according to an embodiment.

First, referring to FIG. 3, the display area according to an embodiment includes a red light emitting region RLA, a green light emitting region GLA, and a incident blue light emitting region BLA. A non-light emitting region NLA1 may be arranged between adjacent red light emitting region RLA, green light emitting region GLA, and incident blue light emitting region BLA. Each light emitting region may correspond to a pixel. For example, the incident blue light emitting region BLA, the red light emitting region RLA, and the green light emitting region GLA may correspond to blue pixels, red pixels, and green pixels, respectively.

The cross-sectional view of the display area includes a display portion DC including a light emitting element and a color conversion portion CC in which color conversion particles that convert light provided from the light emitting element into red, green, and incident blue light are arranged. That is, the cross-sectional view of the display area includes a display portion DC with a light-emitting element and a color conversion portion CC where color conversion particles are arranged to convert light from the light-emitting element into red, green, and blue light.

The display unit DC includes a first substrate SUB1. The first substrate SUB1 may include a flexible material such as a plastic material that can bend, fold, and/or roll.

The circuit layer CL is arranged on the first substrate SUB1. The circuit layer CL may include driving elements, signal lines, and pads connected to the light emitting element ED.

A pixel defining layer PDL is arranged on the circuit layer CL. The pixel defining layer PDL may have a pixel opening that overlaps the first electrode E1 and defines a light emitting region. The pixel defining layer PDL may contain an organic material such as polyacrylate resin and/or polyimide resin, or a silica-based inorganic material. The pixel opening may have a planar shape substantially similar to that of the first electrode E1, and may have a diamond or octagonal shape similar to a diamond in a plan view, but the present disclosure is not limited thereto and the pixel opening may have any suitable shape such as a square or polygon.

The light emitting element ED includes a first electrode E1, a light emitting layer EML, and a second electrode E2.

The first electrode E1 is arranged overlapping the pixel opening of the pixel defining layer PDL. The light emitting layer EML arranged on the first electrode E1 may be made of a low-molecular weight organic material or a high-molecular weight organic material such as poly(3,4-ethylenedioxythiophene) (PEDOT).

The light emitting layer EML may be arranged on the first electrode E1 that overlaps the pixel opening of the pixel defining layer PDL, and may also be arranged on the side or on the pixel defining layer PDL. The light emitting layer EML may have a multilayer structure that further includes one or more from among a hole injection layer, a hole transporting layer, an electron transporting layer, and an electron injection layer.

The second electrode E2 is arranged on the light emitting layer EML. The second electrode E2 may be arranged across a plurality of pixels and may receive a common voltage through a common voltage transmitter in the non-display area.

In an embodiment, the first electrode E1 may be an anode, which is a hole injection electrode, and the second electrode E2 may be a cathode, which is an electron injection electrode. However, the embodiment is not necessarily limited thereto, and the first electrode E1 may be a cathode and the second electrode E2 may be an anode depending on the driving method of the organic light emitting display device.

Holes and electrons are injected into the light emitting layer EML from the first electrode E1 and the second electrode E2, respectively, and light emission occurs if (e.g., when) the exciton that is a combination of the injected holes and electrons falls from the excited state to the ground state. Accordingly, the light emitting element ED can provide light toward the transmission layer TL and the color conversion layers CCL1 and CCL2 within the display area. In one or more embodiments, light emitted from the light emitting element ED may include incident blue light. That is, the light emitting element ED may emit only blue light, and blue light is also referred to as incident blue light throughout the specification. In one or more embodiments, the light emitted from the light emitting element ED may be incident blue light alone or may be a mixture of incident blue light and green light. In one or more embodiments, light emitted from the light emitting element ED may include all of incident blue light, green light, and red light. That is, the light emitting element ED may emit only blue light, a mixture of blue light and green light, or all of blue light, green light, and red light.

An encapsulation layer ENC is arranged on the second electrode E2. The encapsulation layer ENC may include multiple layers and may be formed as a composite layer that includes both (e.g., simultaneously) inorganic and organic layers. In one or more embodiments, the encapsulation layer ENC may be formed with a triple layer structure including (e.g., consisting of) a first inorganic layer EIL1, an organic layer EOL, and a second inorganic layer EIL2 sequentially formed.

The encapsulation layer ENC seals the light emitting element, which is vulnerable to moisture and oxygen, from the top and sides and blocks the inflow of external moisture and oxygen. However, if (e.g., when) the encapsulation layer ENC includes a plurality of layers, the distance between the light emitting element and the color conversion layer CCL increases. As such, the distance light travels from the light emitting element to the color conversion layer CCL increases. Therefore, the amount of light (radiation) that quantum dots QD can absorb in the color conversion layer CCL may decrease.

The color conversion unit CC is arranged on the encapsulation layer ENC.

The color conversion unit CC may or may not include (e.g., may exclude) the second substrate SUB2. In the case of the display device that does not include the second substrate SUB2, an encapsulation layer covering the top and sides of the color conversion unit CC may be arranged to protect the outer portion of the display device. If (e.g., when) the display device includes the second substrate SUB2, the second substrate SUB2 may be arranged overlapping the first substrate SUB1. The second substrate SUB2 may include a flexible material such as plastic that can bend, fold, or roll easily.

The color conversion unit CC may include a partition wall BK arranged on the encapsulation layer ENC. The partition wall BK may include a first opening OP1, a second opening OP2, and a third opening OP3 that overlap the pixel opening of the pixel defining layer PDL. The sizes of the first opening OP1, the second opening OP2, and the third opening OP3 may be different or the same.

The incident blue light emitting region BLA and the corresponding transmission layer TL are arranged in the first opening OP1.

The interior of the transmission layer TL may include a polymer resin. For example, the transmission layer TL may be formed of a polymer resin, e.g., without any quantum dots. Because the transmission layer TL does not include quantum dots QD, the incident blue light is not converted by the transmission layer TL and passes through the transmission layer TL to be emitted as the incident blue light.

The red light emitting region RLA and a corresponding first color conversion layer CCL1 are arranged within the second opening OP2, and a green light emitting region GLA and a corresponding second color conversion layer CCL2 are arranged within the third opening OP3.

The first color conversion layer CCL1 and the second color conversion layer CCL2 may include quantum dots QD. Blue radiant light (e.g., the incident blue light) supplied to the first color conversion layer CCL1 is converted into red light by quantum dots QD, and blue radiant light (e.g., the incident blue light) supplied to the second color conversion layer CCL2 is converted into green light by quantum dots QD. After blue radiation (e.g., the incident blue light) is converted by quantum dots QD, red light is emitted from the first color conversion layer CCL1, and green light is emitted from the second color conversion layer CCL2.

The ratio of the amount of light converted to red or green by absorbing the radiation (e.g., the incident blue light) by quantum dots QD compared to the total blue radiation is called conversion efficiency. Display devices with high conversion efficiency can produce vivid colors.

In order to increase conversion efficiency, a scatterer SC may be included in the first color conversion layer CCL1, the second color conversion layer CCL2, and the transmission layer TL. The scatterer SC plays a role in refracting (e.g., redirecting) the direction of synchronized light toward the quantum dots QD. As a result, the amount of light reaching the quantum dots QD increases, and the amount of light absorbed by the quantum dots QD also increases.

A filling layer IL may be arranged on the partition wall BK, the first color conversion layer CCL1, the second color conversion layer CCL2, and the transmission layer TL. The filling layer IL may provide one display panel by bonding components bonded on the first substrate SUB1 and components bonded on the second substrate SUB2.

Color filters CF1, CF2, and CF3 may be arranged on the filling layer IL. The first color filter CF1 overlaps with the transmission layer TL, the second color filter CF2 overlaps with the first color conversion layer CCL1, and the third color filter CF3 overlaps with the second color conversion layer CCL2.

The first, second, and third color filters CF1, CF2, and CF3 are made of a photosensitive resin and may each contain a dye that exhibits a unique color. Thus, the first color filter CF1 only allows incident blue light with wavelengths in a range of 450 nm to 495 nm to pass through, the second color filter CF2 only allows red light with wavelengths in a range of 495 nm to 570 nm to pass through, and the third color filter CF3 can only allow green light with wavelengths in a range of 630 nm to 780 nm to pass through.

Because each color filter absorbs light in wavelength ranges other than the set or predetermined wavelength for red or green light, incident blue light emitted outside the display device on the first color filter CF1, red light emitted outside the display device on the second color filter CF2, and green light emitted outside the third color filter CF3 can have increased purity.

Color filters CF1, CF2, and CF3 according to an embodiment can reduce external light reflection of the display device. For example, if (e.g., when) external light reaches the first color filter CF1, only the preset (e.g., set or predetermined) light can pass through the first color filter CF1, and light of other wavelengths can be absorbed by the first color filter CF1. Accordingly, among the external light incident on the display device, only light of a preset (e.g., set or predetermined) wavelength passes through the first color filter CF1, and a portion of it is reflected by the electrode below and can be emitted to the outside again. For example, only some of the external light incident on the incident blue light emitting region BLA is reflected to the outside, so the first color filter CF1 can play a role in reducing external light reflection. This description can also be applied to the second color filter CF2 and third color filter CF3.

At least two from among the first, second, and third color filters CF1, CF2, and CF3 may overlap in the non-light emitting region NLA1 to serve as a light blocking layer. Therefore, the color filters CF1, CF2, and CF3 can prevent or reduce color mixing without (e.g., the inclusion of) a light blocking layer. However, the structure of the embodiment is not necessarily limited thereto, and the display device may include a black mattress layer on the color filters CF1, CF2, and CF3.

In some embodiments, a protective layer may be arranged between the color conversion layer and the filling layer IL, and between the color filters CF1, CF2, and CF3 and the filling layer IL.

Hereinafter, the structure and function of the quantum dots and scatterers included in each color conversion layer will be described in more detail with reference to FIGS. 4(a)-4(b). FIG. 4(a) is a schematic perspective view of the color conversion layer if (e.g., when) it has monodispersed scatterers, and FIG. 4(b) is a schematic perspective view of the color conversion layer if (e.g., when) it has polydispersed scatterers.

Referring to FIG. 4(a), the scatterer SC containing TiO₂ in a color conversion layer CCL is monodispersed. The monodispersed state refers to that the first scatterer SC1, the second scatterer SC2, and the third scatterer SC3 all have the substantially same particle size (e.g., a particle size of one). That is, in an example of the color conversion layer CCL with a monodispersed scatterer SC containing TiO₂, the monodispersed state refers to that the first scatterer SC1, the second scatterer SC2, and the third scatterer SC3 all have substantially the same particle size. This refers to that all the particles in the monodispersed state have the same size, ensuring uniformity in their distribution and behavior.

The color conversion layer CCL may include a base resin BR and quantum dots QD and scatterers SC1, SC2, and SC3 particles dispersed in the base resin BR. For example, the color conversion layer CCL may be filled (e.g., deposited) by an inkjet process (method).

The base resin BR may be made of one or more suitable resin compositions, which may generally be referred to as binders. However, the present disclosure is not limited thereto, and any suitable medium that can distribute the first, second, and third scatterers SC1, SC2, and SC3 as described in this specification may be applicable regardless of its name, additional functions, composition materials, and/or the like. The base resin BR may be a polymer resin. For example, the base resin BR may be an acrylic resin, a urethane resin, a silicone resin, an epoxy resin, and/or the like. Additionally, the base resin BR may be a transparent resin.

Quantum dots QD may be selected from among Group II-VI compounds, Group III-V compounds, Group IV-VI compounds, Group IV elements, Group IV compounds, and combinations thereof.

The Group II-VI compounds include binary compounds selected from among (e.g., selected from the group consisting of) CdSe, CdTe, ZnS, ZnSe, ZnTe, ZnO, HgS, HgSe, HgTe, MgSe, MgS, and mixtures thereof; ternary compounds selected from among (e.g., selected from the group consisting of) AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and quaternary compounds selected from among (e.g., selected from the group consisting of) HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-V compounds include a binary compound selected from among (e.g., selected from the group consisting of) GaN, GaP, GaAs, GaSb, AlN, AlP, AlAs, AlSb, InN, InP, InAs, InSb, and mixtures thereof; a ternary compound selected from among (e.g., selected from the group consisting of) GaNP, GaNAs, GaNSb, GaPAs, GaPSb, AlNP, AlNAs, AlNSb, AlPAs, AlPSb, InGaP, InNP, InNAs, InNSb, InPAs, InPSb, and mixtures thereof; and a quaternary compound selected from among (e.g., selected from the group consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compounds include a binary compound selected from among (e.g., selected from the group consisting of) SnS, SnSe, SnTe, PbS, PbSe, PbTe, and mixtures thereof; a ternary compound selected from among (e.g., selected from the group consisting of) SnSeS, SnSeTe, SnSTe, PbSeS, PbSeTe, PbSTe, SnPbS, SnPbSe, SnPbTe, and mixtures thereof; and a quaternary compound selected from among SnPbSSe, SnPbSeTe, SnPbSTe, and mixtures thereof. The Group IV elements may be selected from among (e.g., selected from the group consisting of) Si, Ge, and mixtures thereof. The Group IV compound may be a binary compound selected from among (e.g., selected from the group consisting of) SiC, SiGe, and mixtures thereof.

The binary compound, the ternary compound, and the quaternary compound may be present (e.g., exist) in the particle at a substantially uniform concentration, or may be present (e.g., exist) in the same particle with a partially different (e.g., non-uniform) concentration distribution. Additionally, one quantum dot QD may have a core/shell structure around (e.g., surrounding) another quantum dot QD. The interface between the core and the shell may have a concentration gradient in which the concentration of elements present in the shell decreases toward the center of the core. The shell of quantum dots QD may serve as a protective layer to maintain semiconductor properties by preventing or reducing chemical denaturation of the core and/or as a charging layer to impart electrophoretic properties to the quantum dot. The shell may be a single layer or multiple layers.

Quantum dot QD may have an emission wavelength spectrum with a full width at half maximum FWHM of about 45 nm or less, for example, about 40 nm or less, or about 30 nm or less, and within these ranges, color purity and/or color reproducibility can be improved. Additionally, because the light emitted through these quantum dots QD is emitted in all direction, the optical viewing angle can be improved.

Additionally, the form of quantum dots QD is not specifically limited to the commonly used forms in the field, for example, the form of quantum dots QD may be spherical, pyramidal, multi-arm, or cubic nanoparticles, nanotubes, nanowires, nanofibers, or nanoplate particles.

The color of light emitted by quantum dots may be controlled by adjusting the particle size, and accordingly, quantum dots QD can have various suitable emission colors such as blue, red, and/or green.

The scatterers SC1, SC2, and SC3 will be described in more detail. The scatterers SC1, SC2, and SC3 serve to increase the conversion efficiency by refracting light.

In an embodiment, the first scatterer SC1, the second scatterer SC2, and the third scatterer SC3 are dispersed in particulate form within the color conversion layer CCL. In this embodiment, the first scatterer SC1, the second scatterer SC2, and the third scatterer SC3 are all in a monodispersed state (e.g., have the substantially same particle size) with a particle size of 1.

At least one of the first scatterer SC1, the second scatterer SC2, or the third scatterer SC3 may be made of any suitable material from among metals and metal oxides to evenly scatter light. For example, at least one of the first scatterer SC1, the second scatterer SC2, or the third scatterer SC3 can be at least one selected from among TiO₂, ZrO₂, Al₂O₃, In₂O₃, SiO₂, ZnO, Sb₂O₃, ITO, and SnO₂. However, in an embodiment, the first scatterer SC1, the second scatterer SC2, and the third scatterer SC3 may include titanium dioxide TiO₂. That is, the first scatterer SC1, the second scatterer SC2, and the third scatterer SC3 may each include (e.g., be made of) titanium dioxide TiO₂. When made of titanium dioxide TiO₂, the scatterers SC1, SC2, and SC3 mostly have a spherical or substantially spherical shape.

In the scatterers SC1, SC2, and SC3 composed of spherical polycrystalline particles, the diameter of the spherical particles (e.g., polycrystalline TiO₂ particles) may be about 100 nm to about 180 nm. When the scatterers SC1, SC2, and SC3 have a diameter of 100 nm or more, the minimum scattering angle necessary or desirable to increase conversion efficiency may be obtained or secured.

However, as the size of the scatterers SC1, SC2, and SC3 increases, the scattering reflection due to external light increases and the contrast ratio of the display device decreases. In order to reduce scattering reflection, the size (e.g., diameter) of the scatterers SC1, SC2, and SC3 may be limited to about 180 nm or less. For example, by limiting the increase in the refraction angle of the radiation incident on the scatterers SC1, SC2, and SC3, it is possible to prevent or substantially prevent the amount of light (e.g., scattered or reflected light) emitted outside the display device from increasing. This can prevent reflected light from increasing. In the present disclosure, when scatters or scatters particles are spherical, “diameter” or “size” indicates a particle diameter or an average particle diameter, and when the scatters or scatter particles are non-spherical, the “diameter” or “size” indicates a major axis length or an average major axis length. The diameter or size of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D₅₀ refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

Referring FIG. 4(b), the scatterers SC made of TiO₂ are polydispersed (e.g., with particles of different diameters from one another). Descriptions of the same components as those described in FIG. 4(a) will not be repeated.

The scatterers SC1, SC2, and SC3 will be described in more detail. In this embodiment, the first scatterer SC1, the second scatterer SC2, and the third scatterer SC3 are in a polydispersed state containing two or more different particle sizes. That is, in the present context, a polydisperse state refers to a condition where particles within a mixture have varied sizes. Unlike a monodisperse state, where all particles are of uniform size, a polydisperse state includes particles of different diameters. This variation can affect the properties and behavior of the material, such as light scattering and distribution.

The average diameter (hereinafter referred to as D_{avg} or D₅₀) of the scatterers SC1, SC2, and SC3 is about 140 nm to about 160 nm. When the average diameter of the scatterers SC1, SC2, and SC3 is 140 nm or more, the minimum scattering angle necessary or desirable to increase the conversion efficiency may be secured or obtained. In addition, when the average diameter of the scatterers SC1, SC2, and SC3 is 160 nm or less, the amount of reflected light scattered or diminished by external light is limited or reduced.

Because the refractive index of the scatterers SC1, SC2, and SC3 is affected by their sizes, the range of variation in the particle sizes is limited, e.g., to a range. In an embodiment, the particle size value (hereinafter referred to as D₁₀) if (e.g., when) the cumulative distribution percentage of particles in the particle size distribution of scatterers SC1, SC2, and SC3 reaches 10% is at least the value obtained by subtracting 50 nm from D_{avg}. That is, D₁₀, the particle size corresponding to the cumulative distribution percentage of particles in the particle size distribution of 10%, is at least the value obtained by subtracting 50 nm from D_{avg}. Additionally, the particle size value if (e.g., when) the cumulative distribution percentage of the particle size distribution of TiO₂ reaches 90% (hereinafter referred to as D₉₀) is less than or equal to the average particle size of TiO₂ D_{avg} plus 100 nm, or less than or equal to D_{avg} plus 50 nm. That is, D₉₀, the particle size corresponding to the cumulative distribution percentage of particles in the particle size distribution of 90%, is not greater than D_{avg} plus 100 nm.

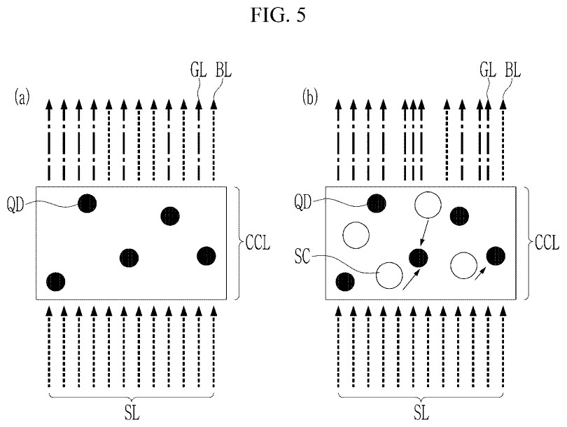

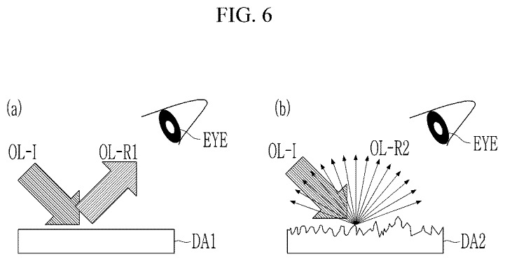

Hereinafter, the effect of the display panel according to an embodiment will be described with reference to FIGS. 5(a)-6(b). FIG. 5(a) is a schematic diagram of a color conversion layer without scatterers, and FIG. 5(b) is a schematic diagram of a color conversion layer with scatterers. FIG. 6(a) is a diagram showing a surface on which incident light is mirror-reflected, and FIG. 6(b) is a diagram showing a surface on which incident light is scattered and reflected.

In FIGS. 5(a)-5(b), the role of the scatterer SC is explained using the color conversion layer CCL including green quantum dots QD as an example.

When the light SL emitted from the light emitting element reaches the color conversion layer CCL, as shown in FIG. 5(a), in the absence of the scatterers SC, a relatively large amount of the light SL does not reach the quantum dots QD and escapes from the color conversion layer CCL (e.g., is emitted from the color conversion layer CCL as the incident blue light BL). Therefore, there is a relatively large amount of incident blue light BL that is emitted without being converted to green light GL. That is, light emitted from the color conversion layer CCL includes both green light GL and a relatively large amount of the incident blue light BL.

When the light SL from the light emitting element reaches the color conversion layer CCL, as shown in FIG. 5(b), if there is the scatterers SC, the scatterers SC act to refract the direction of the radiation (e.g., light) towards the quantum dots QD. Therefore, the color conversion efficiency of quantum dots QD is higher, and relatively less incident blue light BL is emitted without being converted to green light GL in comparison to the color conversion layer shown in FIG. 5(a).

The concentration (e.g., amount) of the scatterers SC in the color conversion layer CCL may be more than 4 wt % of a concentration of the quantum dot. Within this range, the amount of light reaching the quantum dots QD may be increased. In an embodiment, the amount of the scatterers SC may be 4 wt % or greater based on the total weight (100 wt %) of the quantum dots. In other words, a ratio between a weight amount of the scatterer and a weight amount of the quantum dots in the color conversion layer CCL is 4:100 or greater.

This explanation can also be applied to the red color conversion layer.

FIGS. 6(a)-6(b) show the scattered reflection that may occur on the surface of the scatterers.

FIG. 6(a) illustrates the reflected light OL-R1 generated by the reflection of the incident light OL-I on the smooth surface DA1, and FIG. 6(b) shows the scattered reflected light OL-R2 generated by the scattering reflection of the incident light OL-I on the rough surface DA2.

The reflectance including both the reflected light OL-R1 and the scattered reflected light OL-R2 is called SCI (specular component included), and the reflectance with the reflected light OL-R1 removed from SCI is called SCE (specular component excluded).

When scatterers are present as shown in FIG. 5(b), the reflection decreases, but the scattered reflection increases compared to the color conversion layer without the scatterers. To reduce scattered reflections, the reflected light or scatterers may be reduced.

Scattered reflected light has greater intensity in the following order: green, red, and blue. When the size of the scatterers is limited (e.g., reduced), the change in reflectance of incident blue light is relatively small because the initial amount of reflected light is not large, but the scattered reflectance of green light and red light, which has a higher scattered reflection intensities, decreases in that order. Therefore, their SCE decreases in that order.

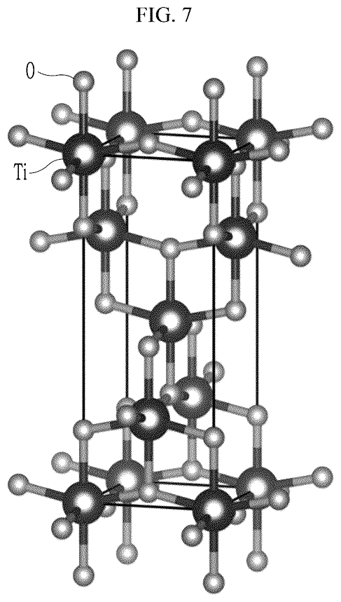

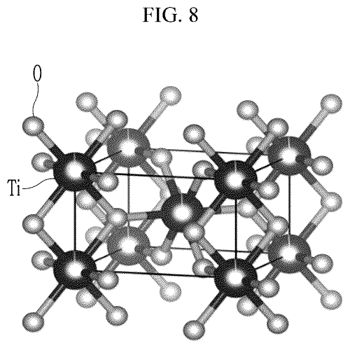

Hereinafter, with reference to FIGS. 7 and 8, the structure of the scatterer included in the display panel according to an embodiment will be described. FIG. 7 is a diagram showing the structure of the anatase form of TiO₂ corresponding to the scatterer in an embodiment, and FIG. 8 is a diagram showing the structure of the rutile form of TiO₂ corresponding to the scatterer in an embodiment.

FIG. 7 shows a structure of the anatase form of TiO₂, which is the form obtained if (e.g., when) the size of the grains constituting the polycrystalline particles of TiO₂ is small. This form of the grain is possible both (e.g., simultaneously) if (e.g., when) TiO₂ is monodispersed and if (e.g., when) it is polydispersed. That is, both monodispersed TiO₂ and polydispersed TiO₂ may have the anatase form.

In an embodiment having monodispersed titanium dioxide TiO₂ as a scatterer, if (e.g., when) the scatterer is in the anatase form, the grain size of the scatterer is about 20 nm to about 30 nm.

FIG. 8 shows a structure of the rutile form of TiO₂ with an octahedral structure, which is obtained if (e.g., when) the size of the grains constituting the polycrystalline particles of TiO₂ is small. It has a higher density compared to the anatase form. This form of the grain is possible both (e.g., simultaneously) if (e.g., when) TiO₂ is monodispersed and if (e.g., when) it is polydispersed. That is, both monodispersed TiO₂ and polydispersed TiO₂ may have the rutile form.

In an embodiment, having monodisperse titanium dioxide TiO₂ as a scatterer, if (e.g., when) the scatterer is rutile form, the grain size of the scatterer is about 20 nm to about 30 nm.

If (e.g., when) TiO₂ is monodispersed, the grains constituting the polycrystalline particles of titanium dioxide TiO₂ may have an amorphous form if the grain size is large.

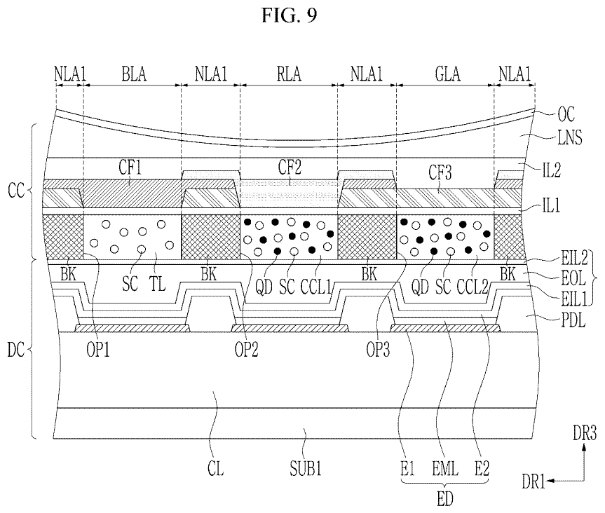

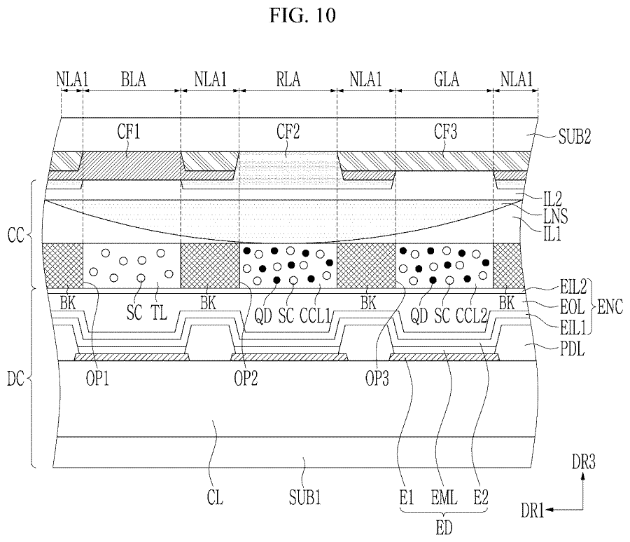

Hereinafter, the display device including a structure for correcting a white coordinate system according to an embodiment will be described with reference to FIGS. 9 to 11. The structure that corrects the white coordinate system may be a micro-lens array, and FIGS. 10 to 12 are cross-sectional views of a display panel including a micro-lens array according to an embodiment.

Referring to FIG. 9, the display device has a structure including the scatterer in a color conversion layer and one substrate thereof further includes a micro-lens array. Because it has substantially the same structure as the display device of FIG. 3 except for those described below, descriptions of the same components as those described in FIG. 3 will not be provided.

A first insulating layer IL1 and a micro-lens array LNS are arranged on the color filters CF1, CF2, and CF3. A micro-lens array LNS may be made of a transparent resin. For example, it may include photocurable resins such as epoxy acrylate-based resins, urethane acrylate-based resins, and/or silicone acrylate-based resins, or thermosetting resins such as acrylic resins, urethane-based resins, and/or polyester-based resins. The resin constituting the micro-lens array LNS may have a light transmittance of 90% or more, but the present disclosure is not limited thereto.

A micro-lens array LNS may have a high refractive index of 1.5 or more. Furthermore, the micro-lens array LNS may be made of a high refractive index material with a refractive index of 1.6 or more.

The micro-lens array LNS includes surface irregularities. The surface of the micro-lens array LNS includes a plurality of concave portions and convex portions arranged between the plurality of concave portions. The concave portions have a concave-shaped cross-section. Because the micro-lens array LNS plays a role in scattering light, it may have a concave shape in the downward direction in the cross-sectional view. However, FIG. 9 is a vertical cross-sectional view of the display device, and only one micro lens among the micro-lens array LNS having a plurality of concave portions is shown.

Additionally, in some embodiments, the micro-lens array LNS may extend in one direction. For example, the lens may have a line shape in a plane view. Each lens constituting the micro-lens array LNS may extend in the short side direction of the display device. A plurality of lenses are arranged in a direction that intersects the extension direction of the micro-lens array LNS.

A second insulating layer IL2 and an overcoat layer OC are arranged on the micro-lens array LNS. The overcoat layer OC may be made of an acrylic epoxy material, but the present disclosure is not limited thereto. A difference between the refractive index of the overcoat layer OC and that of the lenses constituting the micro-lens array LNS may be 0.05 or more. For example, if the refractive index of the lens constituting the micro-lens array LNS is 1.5, the refractive index of the overcoat layer OC may be 1.55. The overcoat layer OC may serve to planarize the layer of the micro-lens array LNS and protect the plurality of wavelength conversion patterns and light transmission patterns.

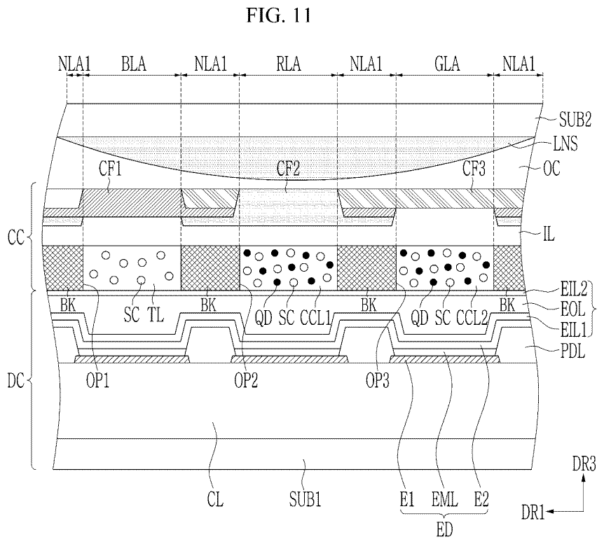

Referring to FIGS. 10 and 11, the display device includes the scatterers in a color conversion layer, two substrates, and a micro-lens array.

The color filters CF1, CF2, and CF3 may be arranged on the first substrate SUB1 or the second substrate SUB2 of the display device.

Referring to FIG. 10, the display device according to an embodiment may include color filters CF1, CF2, and CF3 arranged between the second substrate SUB2 and the color conversion layers CCL1 and CCL2, a microlens array LNS arranged between the color filters CF1, CF2, and CF3 and the color conversion layers CCL1 and CCL2, and insulating layers IL1 and IL2 arranged above and below the microlens array LNS.

The insulating layer IL1 may be replaced with the filling layer according to an embodiment. The filling layer serves to combine (e.g., tightly combine) the components arranged on the first substrate SUB1 and the components arranged on the second substrate SUB2. One display panel can be formed through the filling layer. That is, by combining the components arranged on the first substrate SUB1 and the components arranged on the second substrate SUB2 through the filling layer, a display panel as a singular body may be formed.

The micro-lens array LNS includes a plurality of concave portions on the surface, and the concave portions are concaved downward (e.g., have a concave shape in the downward direction) in a cross-sectional view. Only a single micro lens is shown in the drawing.

The structure of the display device in which a color filter is arranged on the second substrate of the display device will be described in more detail.

The display device of FIG. 10 includes a structure in which color filters CF1, CF2, and CF3 are arranged on top of a micro-lens array LNS.

The micro-lens array LNS arranged on the second substrate SUB2 includes a plurality of convex parts and concaved parts arranged between the plurality of convex parts. The convex parts have a convex cross-section. Therefore, if (e.g., when) bonding to the first substrate SUB1, it is bonded in an overturned state, so that the cross-section is concaved downward toward the first substrate SUB1.

The display device of FIG. 11 includes a structure in which color filters CF1, CF2, and CF3 are arranged below the micro-lens array LNS. Therefore, on the second substrate SUB2, a micro-lens array LNS is arranged, the overcoat layer OC is placed on the micro-lens array LNS, and color filters CF1, CF2, and CF3 that are arranged on the overcoat layer OC can be arranged.

The micro-lens array LNS has a convex cross-sectional shape.

the refractive index of the overcoat layer OC may be smaller than that of the lenses constituting the micro-lens array LNS, and a difference between the refractive index of the overcoat layer OC and that of the lenses constituting the micro-lens array LNS may be greater than 0.05. Within this range, the light emitted through the micro-lens array LNS may be suitably scattered.

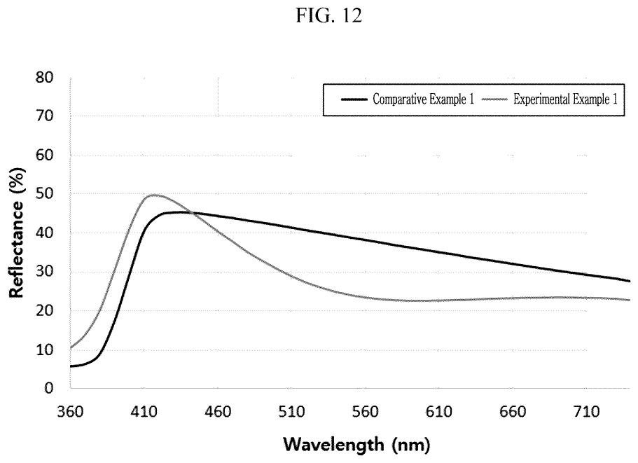

The reflectance of Embodiment 1 and Comparative Example 1 is described through FIG. 12. FIG. 12 is a graph showing the reflectance of a display panel according to an embodiment and that of a comparative display panel.

### Experimental Example 1

A display device according to Experimental Example 1 (or Embodiment 1 according to the present disclosure) uses polycrystalline TiO₂ particles as scatterers, which are spherical with a diameter of 130 nm, and in rutile form. TiO₂ scatterers are monodispersed and arranged in the color conversion layer on the display device at a concentration (e.g., amount) of 4 wt % compared to the total quantum dots. That is, the weight amount of the TiO₂ scatterers is 4 wt % based on the total weight (100 wt %) of the quantum dots.

In the display device of Experimental Example 1, the effective refractive index of the scatterers is 2.49.

### Comparative Example 1

A display device according to Comparative Example 1 uses scatterers of polycrystalline TiO₂ particles, which have an average particle size D_{avg} of 180 nm, a D₉₀ of 360 nm, and are in rutile form. TiO₂ scatterers are polydispersed and are 4 wt % of a concentration (e.g., amount) of the quantum dots in the color conversion layer. That is, the weight amount of the TiO₂ scatterers is 4 wt % based on the total weight (100 wt %) of the quantum dots.

The graph in FIG. 12 shows the SCE reflectance according to the wavelength of Example 1 and Comparative Example 1.

The SCE reflectance of the display device at a wavelength of 550 nm is 56% of the SCE reflectance at a wavelength of 450 nm, and 60% of the reflectance at a wavelength of 460 nm. The SCE reflectance of the display device at a wavelength of 650 nm is 54% of the SCE reflectance at a wavelength of 450 nm, and 57% of the SCE reflectance at a wavelength of 650 nm. For example, it can be seen that the SCE reflectance decreases in the order of the red light region belonging to 495 nm to 570 nm and the green light region belonging to 630 nm to 780 nm.

Compared to the display device of Comparative Example 1, at a wavelength of 450 nm, the SCE reflectance of Example 1 is 97% that of Comparative Example 1, and at a wavelength of 460 nm, the SCE reflectance of Example 1 is 91% that of Comparative Example 1. For example, it can be seen that in the incident blue light region belonging to 450 nm to 495 nm, the SCE reflectance is not significantly affected by changes in the size of the scatterers.

Increasing or decreasing the concentration of scatterers can increase or decrease the SCE reflectance of the display device. For example, to make the SCE reflectance of Example 1 the same as that of Comparative Example 1 at a wavelength of 460 nm, the concentration (e.g., amount) of TiO₂ scatterers may be increased by 0.5 wt % to 4.5 wt %. The reflectance of Example 1 at a wavelength of 550 nm increases from the previous 24 wt % to 26.5 wt %, and at a wavelength of 650 nm, the reflectance of Example 1 increases from the previous 23.2 wt % to 25.6 wt %. Conversely, if (e.g., when) the content (e.g., amount) of scatterers is lowered, the SCE reflectance at wavelengths of 450 nm and 460 nm decreases, but the luminance of the display device also decreases.

Compared to the display device without the scatterers, the SCI reflectance of the display device without the scatterer is 1.5% and the SCE reflectance is 0.05%, and the SCI reflectance of the display device of Comparative Example 1 is 1.3% and the SCE reflectance is 0.9%, and the SCI reflectance of the display device of Example 1 is 1.12% and the SCE reflectance is 0.82%. For example, in a display device including scatterers, the SCI reflectance is lower but the SCE reflectance is higher, and resizing (e.g., changing the sizes of) the scatterers as in an embodiment of the present disclosure reduces the SCE reflectance.

As used herein, the term “and/or” includes any and all combinations of one or more of the associated listed items. Throughout the disclosure, the expression “at least one of a, b and c”, “at least one of a, b or c”, “at least one selected from a, b, and c”, “at least one selected from the group consisting of a, b, and c”, “at least one from among a, b, and c”, “at least one of a to c”, etc., indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It will be understood that, although the terms first, second, third, and/or the like, may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

A display manufacturing device, a display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Although some embodiments of the present disclosure have been described in more detail above, the scope of the present disclosure is not limited thereto, and one or more suitable modifications and improvements made by those skilled in the art using the basic concepts of the present disclosure defined in the following claims and equivalents thereof are also possible. It should be understood by those skilled in the art that one or more suitable changes, substitutions, and alternations may be made therein without departing from the scope of the disclosure as defined by the following claims and equivalents thereof.

### REFERENCE NUMERALS

SC: scatterers
QD: quantum dots
CCL1: first color conversion layer
CCL2: second color conversion layer
LNS: micro-lens array
OC: overcoat layer
SUB1: first substrate
SUB2: second substrate
ED: light emitting element

What is claimed is:

1. A display device, comprising:
a display panel; and
a color conversion layer on the display panel,
wherein,
the color conversion layer comprises a quantum dot and a scatterer,
the scatterer comprises a first particle having a first diameter, and
the first diameter is about 100 nm to about 180 nm.

2. The display device of claim 1, wherein
the scatterer is TiO₂.

3. The display device of claim 2, wherein
the scatterer has a spherical shape.

4. The display device of claim 3, wherein
a grain form of the scatterer comprises at least one of rutile or anatase.

5. The display device of claim 4, wherein
the scatterer has an average grain size of about 20 nm to about 30 nm.

6. The display device of claim 1, wherein
the display panel comprises:
a first substrate; and
a light emitting element on the first substrate,
wherein the color conversion layer is on the light emitting element, and
wherein the scatterer is dispersed in particulate form within the color conversion layer.

7. The display device of claim 6, wherein
the scatterer is 4 wt % or greater in amount based on a total weight of the quantum dot.

8. The display device of claim 1, further comprising:
a color filter on the color conversion layer; and
a micro-lens array overlapping the color filter.

9. The display device of claim 8, wherein
the micro-lens array has a refractive index of 1.5 or more.

10. The display device of claim 9, further comprising
an overcoat layer overlapping the micro-lens array,
wherein a refractive index of the overcoat layer exceeds that of lenses constituting the micro-lens array by at least 0.05.

11. A display device, comprising:
a display panel; and
a color conversion layer on the display panel,
wherein,
the color conversion layer comprises a quantum dot and a scatterer,
the scatterer comprises at least two particles with different diameters, and
the particles have diameters in a range of about 140 nm to about 160 nm.

12. The display device of claim 11, wherein
the scatterer is TiO₂.

13. The display device of claim 12, wherein
the scatterer has a spherical shape.

14. The display device of claim 13, wherein
a grain form of the scatterer comprises at least one of rutile or anatase.

15. The display device of claim 11, wherein
the display panel comprises:
a first substrate; and
a light emitting element on the first substrate,
wherein the color conversion layer is on the light emitting element, and
wherein the scatterer is dispersed in particulate form within the color conversion layer.

16. The display device of claim 12, wherein
a particle size value D₁₀ corresponding to a cumulative distribution percentage of particles in a particle size distribution of TiO₂ of 10% is greater than or equal to an average particle size D_{avg} of TiO₂ minus 50 nm, and
a particle size value D₉₀ corresponding to a cumulative distribution percentage of particles in a particle size distribution of TiO₂ of 90% is less than or equal to the average particle size D_{avg} of TiO₂ plus 50 nm.

17. The display device of claim 12, wherein
a particle size value D₉₀ corresponding to a cumulative distribution percentage of particles in a particle size distribution of TiO₂ of 90% is less than or equal to an average particle size D_{avg} of TiO₂ plus 100 nm.

18. The display device of claim 11, further comprising:
a color filter on the color conversion layer; and
a micro-lens array overlapping the color filter.

19. The display device of claim 18, wherein
the micro-lens array has a refractive index of 1.5 or more.

20. The display device of claim 19, further comprising:
an overcoat layer overlapping with the micro-lens array,
wherein a refractive index of the overcoat layer exceeds that of lenses constituting the micro-lens array by at least 0.05.
